(19) United States
(12) Patent Application Publication
(10) Pub. No.: US 2005/0178660 A1
(43) Pub. Date: Aug. 18, 2005

(54) Sputter arrangement with a magnetron and a target

(76) Inventors: Andreas Lopp, Freigericht-Somborn (DE); Andreas Jischke, Kahl (DE); Michael Geisler, Wachtersbach (DE); Herbert Pfeiffer, Maintal (DE); Jorg Krempel-Hesse, Eckartsborn (DE)

Correspondence Address: FULBRIGHT & JAWORSKI, LLP, 666 FIFTH AVE, NEW YORK, NY, 10103-3198, US

(21) Appl. No.: 10/797,925

(22) Filed: Mar. 10, 2004

(30) Foreign Application Priority Data
Feb. 18, 2004 (DE) 10 2004 007 813.0

(51) Int. Cl. C23C 14/35

(52) U.S. Cl. 204/298.2; 204/298.19

(57) ABSTRACT

The invention relates to a sputter arrangement with a magnetron and a target, with the magnetron and the target being movable relative to one another. The magnetron comprises a magnet system, which forms a quasi-rectangular plasma tube, whose two longitudinal sides have a distance C from one another. If target and magnet system are moved relative to one another by a path corresponding approximately to the distance C, the magnet system is laid out such that the width at the end of the plasma tube is smaller or equal to the diameter of the plasma tube. However, if the path of the relative movement is less than C, the magnet system is laid out such that the width d of the ends of the plasma tube is less or equal to twice the diameter of the plasma tube.

The invention relates to a magnet configuration according to the preamble of patent claim 1.

In a sputter installation a plasma is generated in vacuo in a sputter chamber. Positive ions of the plasma are attracted by the negative potential of a cathode, which is provided with a so-called target. The positive ions impinge on this target and knock out small particles, which can become deposited on a substrate. Knocking out these particles is referred to as “sputtering”. The plasma is comprised of gases which, in the case of non-reactive sputtering, can be inert gases, for example argon. In reactive sputtering, for example, oxygen is utilized alone or together with an inert gas.

To improve the sputter effect, magnets are employed in the proximity of the target, whose magnetic field maintains the plasma on the target. The magnetic field forces the electrons in the plasma into a specific path. The electrons ionize the neutral gas, for example argon, on this path and generate positive ions. These ions are much heavier than the electrons and are practically not affected at all. Instead, they fall onto the target, which acts as a negative electrode or cathode, and sputter it. Ionizations substantially take place where the magnetic field vector extends parallel to the target surface. Here the plasma is densest and therefore the target is here most strongly eroded. In the following the plasma path determined by the magnetic field will also be referred to as a plasma tube.

If planar magnet systems are utilized, in which a bar magnet of a first polarity is surrounded by a rectangular magnet of a second polarity, a rectangular erosion track results between these magnets, with the corners of the rectangle being rounded off.

Rotating cylindrical targets are also already known, which rotate about a stationary magnet aggregate (DE 41 17 518 A1). Hereby the rectangular erosion track reaches all sites of the circumference of the target. At the narrow sides of the erosion rectangle a depression forms in the target. The target is eroded uniformly, except for those sites, at which the narrow sides of the plasma rectangle generated an undesirable depression.

Furthermore, magnet configurations are known, in which in the case of a stationary target the erosion track does not form a rectangle but rather a hexagon (WO 96/21750). This hexagon is comprised of two large sides, which are adjoined by triangles on the right and on the left. Instead of adjoining triangles, parabolas or semi-ellipses can also be provided. The changed erosion contours are attained through the corresponding disposition of the magnets. The magnets can herein be disposed stationarily, while the target rotates about them; but it is also possible for the target to be stationary while the magnets rotate.

However, a sputter arrangement is also known, in which by means of a drive a magnet configuration is moved parallel to the planar surface of the target (U.S. Pat. No. 5,873,989). The movement of the magnet configuration is a back and forth movement, i.e. at the ends of the target it reverses its direction of movement. The plasma forms a plasma track, which has the form of an elongated oval. The longitudinal direction of this oval extends perpendicularly to the direction of movement. In the case of this magnet configuration depressions are also formed close to both ends of the target, which are greater than the erosions in the remaining area of the target. To utilize the target better, the magnet configuration is rotated by 90 degrees after a certain length of time, such that now two further depressions are formed perpendicularly to the depressions previously formed. In the case of this linear arrangement, recessed tracks are consequently generated at the margin of the target in the same way as with a rotation configuration.

The objective of the invention is to avoid erosion depressions at the margin of the target in a linear sputter installation, whose magnets move relative to the target.

This objective is attained through the characteristics of patent claims 1 or 2.

Consequently, the invention relates to a sputter arrangement with a magnetron and a target, with the magnetron and the target being movable relative to one another. The magnetron comprises a magnet system, which forms a quasi-rectangular plasma tube, whose two long sides have a distance C from one another. If target and magnet system are moved relative to one another by a path corresponding to distance C, the magnet system is laid out such that the width at the end of the plasma tube is less or equal to the diameter of the plasma tube. However, if the path of the relative movement is less than C, the magnet system is laid out such that the width d of the ends of the plasma tube is less or equal to twice the diameter of the plasma tube.

Embodiment examples of the invention are depicted in the drawing and will be described in further detail in the following. In the drawing depict:

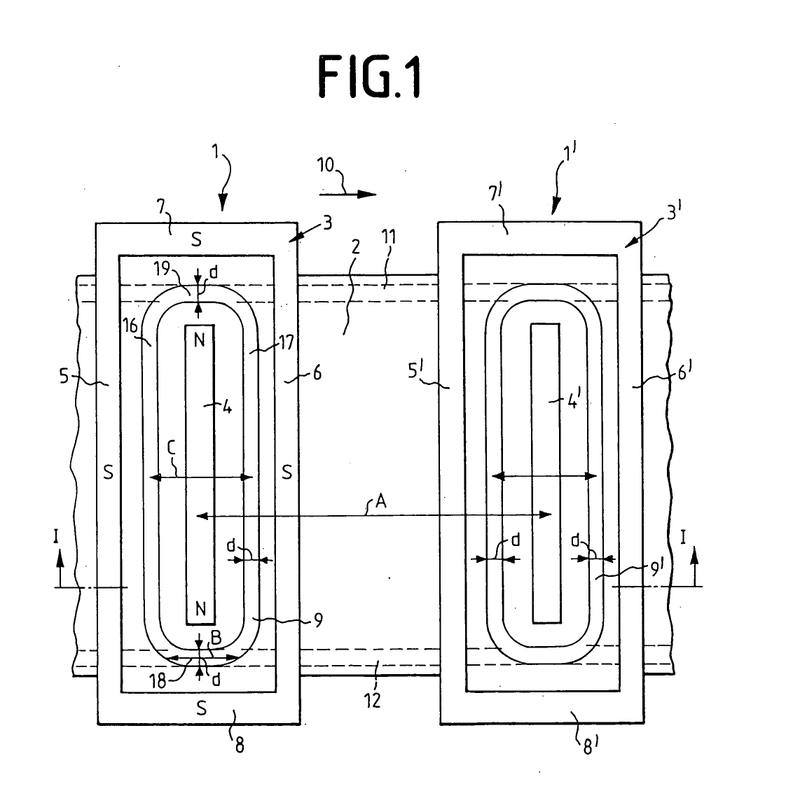

FIG. 1 a fundamental representation of a magnet system which moves over a target,

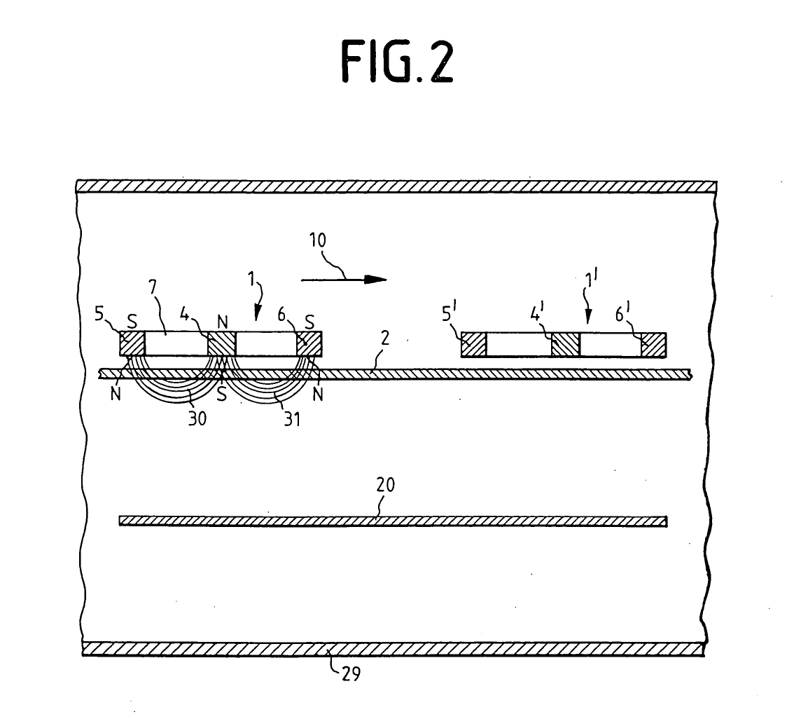

FIG. 2 a section through the configuration of FIG. 1,

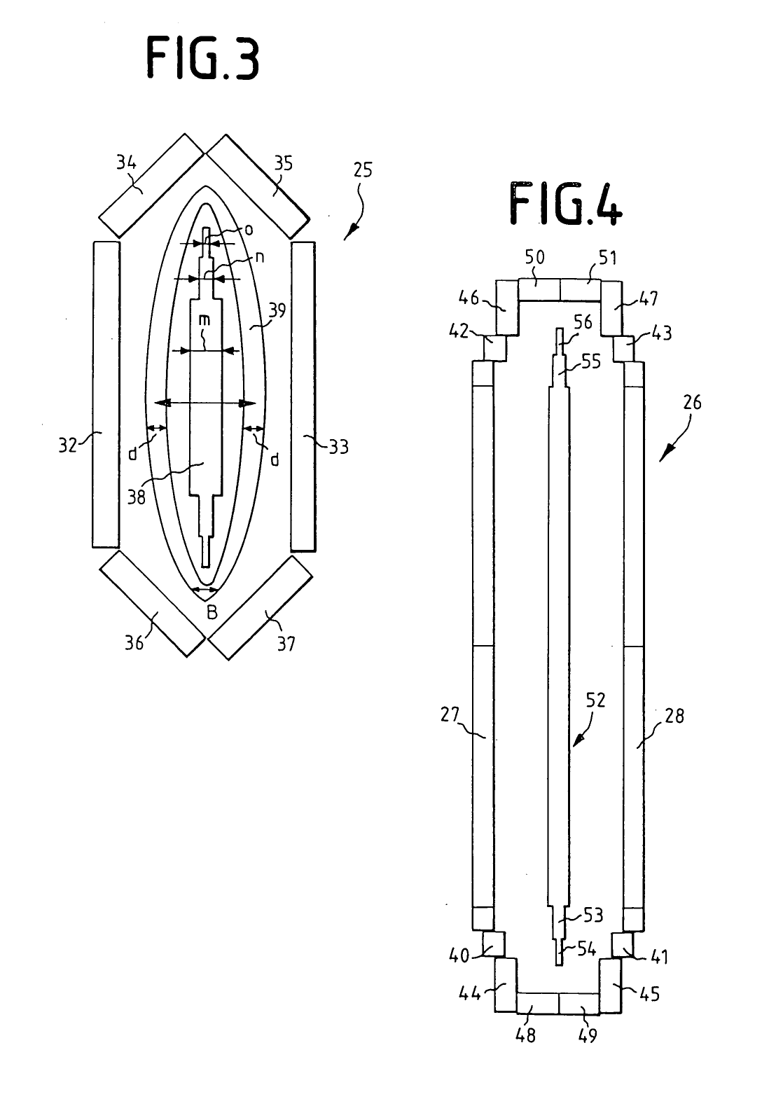

FIG. 3 a magnet system with which uniform erosion of a target can be attained,

FIG. 4 a further magnet configuration with which uniform erosion of a target can be attained,

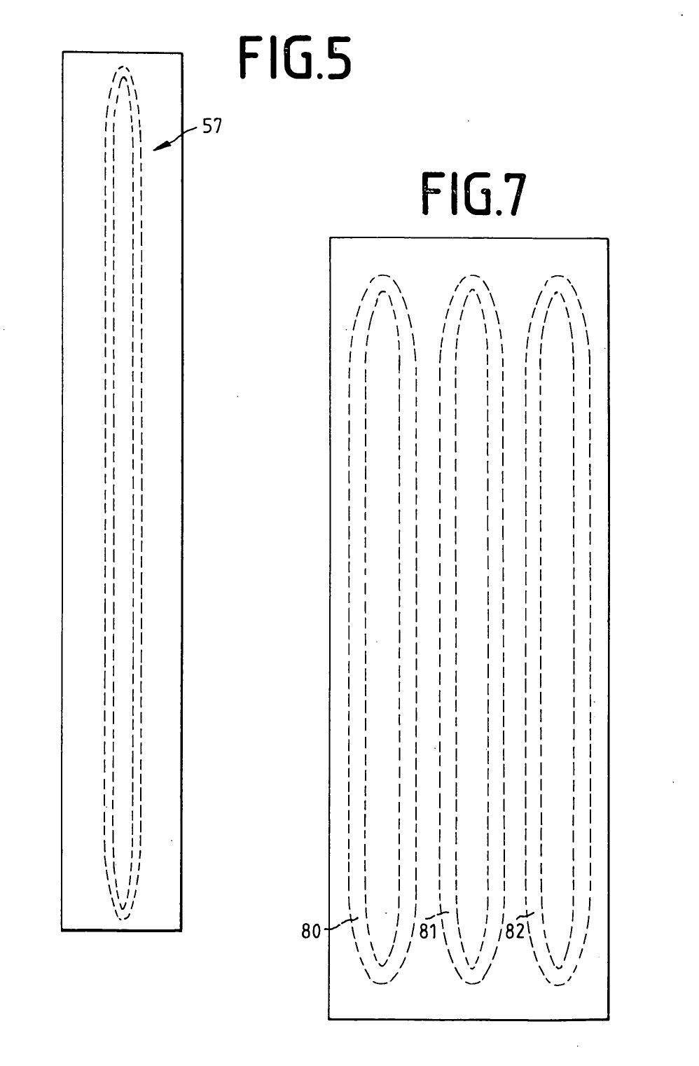

FIG. 5 a plasma tube which can be obtained with a magnet configuration according to FIG. 3 or FIG. 4,

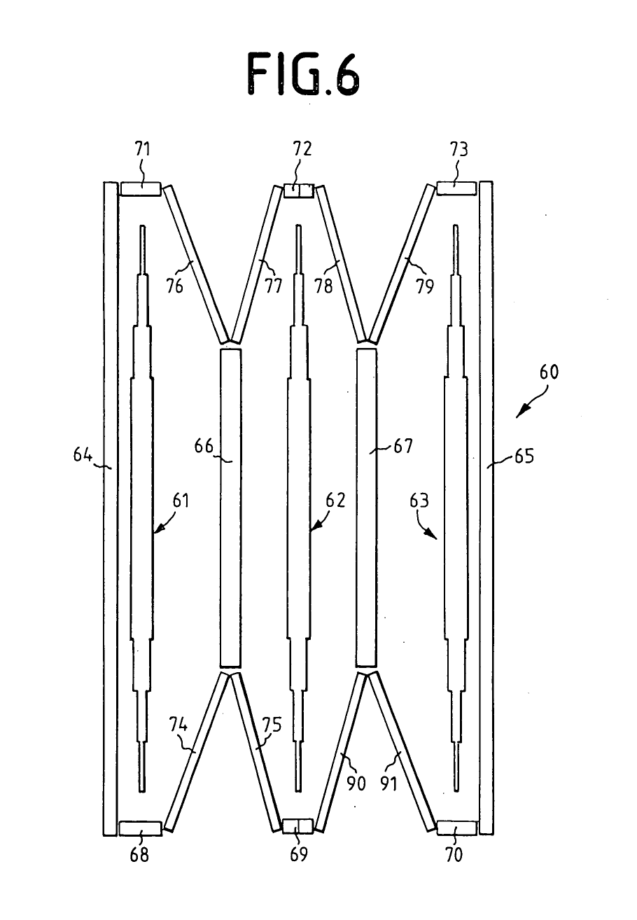

FIG. 6 a further magnet system, which comprises three central magnets;

FIG. 7 plasma tubes generated with the magnet system according to FIG. 6.

FIG. 1 depicts a magnet system 1, disposed above a target 2. The target 2 is comprised of a specific material, which is to be sputtered and deposited on a substrate not shown in FIG. 1. The magnet system 1 comprises an outer magnet 3 in the form of a frame and inner magnet 4 in the form of a bar. The frame is comprised of two long bar magnets 5, 6 and two short bar magnets 7, 8 and the short bar magnets 7, 8 are perpendicular to the long bar magnets 5, 6. Those sides of the long and short bar magnets 5, 6, 7, 8, onto which the view is directed, are, for example, south poles, while that side of the inner magnet 4, onto which the view is directed, is a north pole. On the side not evident facing the target 2, the pole relationships are reversed. The magnetic fields extending on this, not evident, side are curved in the form of a parabola and extend from the outer magnet 3 through the target 2 to the inner magnet 4. Through these magnetic fields electrons are deflected such that a plasma tube 9 is formed, while positively charged particles in the plasma tube, for example argon ions, are accelerated onto the target through an electric field. This plasma tube 9 comprises the vertical regions 16, 17 and the horizontal regions 18, 19. Corresponding to the plasma tube 9, the ions also knock particles out of the non-visible backside of the target 2 in the form of the plasma tube, i.e. in the target a depression is formed in the shape of the plasma tube 9. If the magnet system 1 is moved over the target 2, which remains stationary, in the direction of arrow 10 until it assumes the right position, a substantially identical material erosion takes place on the backside of target 2 with the exception of the outer margin regions of target 2. In the margin region depressions or erosion channels 11, 12 are formed. The reason for the formation of such depressions 11, 12 is the following: at the identical width or thickness d of the vertical and horizontal region of plasma tube 9 the plasma particles impinge in the central region, defined by the length of the inner magnet 4 or the regions 18, 19, onto a strip of 2 d of target 2, however, in the proximity of the upper and lower curvature 18, 19 of plasma tube 9, onto a strip of d×B, where B is the width of the plasma tube in the region of the curvature and d the diameter of the plasma tube. Since d×B>d×2, the upper and lower regions of target 2 are more strongly bombarded with ions than the central region. Consequently the depressions 11, 12 are formed, which are also referred to as erosion trenches.

The magnet system 1′ depicted on the right side is the same magnet system 1 shown on the left side. It only assumes a different position, which is indicated by means of dashed reference numbers. The segment A denotes that segment by which the magnet system 1 is shifted above the target 2 to the right. In many cases the section A is selected such that it corresponds to the section C, i.e. the distance between two long parts 16, 17 of the plasma tube 9.

If the movement to the right corresponds to segment C, the magnetic field is moved such that in the course of the movement each part of the rear target surface is covered once by the plasma. In the case of a large-area target 2 this can be realized with several adjacently disposed magnet systems 1. The direction of movement is in general reversed after segment C has been traversed. The erosion depth on the target 2 can in this case be calculated by integration of the erosion rate along the drive path. As an approximation the erosion can also be estimated by the width d of an arm 16, 17 of plasma tube 9, which migrates over a point on the target surface.

In this case at the upper and lower ends of the plasma tube depressions or erosion channels 11, 12 do not occur if B≦d, provided the plasma density is constant.

In a second embodiment 1 segment A, by which the magnet system 1 is moved, is greater than the distance C between the arms 16, 17. The magnetic field of the magnet system 1 is moved such that during the movement each part of the target surface is covered once by both perpendicular arms of the plasma tube 9. This can again be realized with several magnet systems 1, which are disposed one next to the other. The direction of movement is reversed when the outer margin of the target is reached. The erosion depth can also be calculated in this case through integration of the erosion rate along the drive path. The erosion can be approximately estimated by the sum of all widths d of the plasma tube, which migrate over a point on the target surface. At the upper and lower ends 18, 19 of the plasma tube 9 erosion trenches 11, 12 are not generated only if the width B of the lower or upper arm 19, 18 of the plasma tube 9 corresponds maximally to twice the width d of the plasma tube in the vertical arm, thus if B≦2 d applies, provided the plasma density is constant.

In FIG. 2 a section I-I through the arrangement according to FIG. 1 is shown. Evident are herein magnetic fields 30, 31 which penetrate target 2 parabolically. Beneath target 2 is disposed a substrate 20, which is coated with particles knocked out of the target 2. In the space between target 2 and substrate 20 is disposed a plasma whose positive ions are accelerated onto a (not shown) negative electrode, which, as a rule, forms a unit with the target 2 in the proximity of the magnet system and in this way knock particles out of target 2.

The entire arrangement shown in FIG. 2 is located in a vacuum coating chamber 29.

FIG. 3 shows a special magnet system 25, which comprises two vertical long bar magnets 32, 33 and four smaller bar magnets 34, 35, 36, 37, of which two 34, 35 or 36, 37 in each instance form a type of roof which terminates the ends of the long bar magnets 32, 33.

The inner magnet 38 has different diameters in the longitudinal direction, with the central portion having the larger diameter m and the outer parts having smaller diameters n, o.

FIG. 4 depicts a further magnet system 26, which comprises an outer magnet comprising two long bar magnets 27, 28, two square magnets 40, 41 or 42, 43, disposed offset with respect to them, two small bar magnets 44, 45 or 46, 47 disposed perpendicularly to them, and two small bar magnets 48, 49 or 50, 51 extending perpendicularly to them.

The inner magnet is formed by a bar magnet 52, which comprises at its ends two reductions by steps 53, 54 or 55, 56, with small diameters.

FIG. 5 shows a plasma tube 57, which is attained by means of the magnet system according to FIG. 4.

In FIG. 6 is depicted a further magnet configuration 60, which comprises three inner magnets 61, 62, 63 surrounded by outer magnets. These outer magnets comprise two outer long bar magnets 64, 65, two short bar magnets 66, 67 disposed between them, three end magnets 68, 69, 70, 71, 72, 73 extending in each instance perpendicularly to the bar magnets 64, 65, two thin bar magnets 74, 75 extending obliquely and connecting the lower end of bar magnet 66 with the end magnets 68 or 69, as well as two thin bar magnets 76, 77 extending obliquely and connecting the upper end of the bar magnet with the end magnets 71, 72. Furthermore, the end magnets 69, 70 or 72, 73 are additionally connected via thin bar magnets 78, 79 with the ends of the bar magnet 67.

In FIG. 7 three plasma tubes 80, 81, 82 are depicted, which result if magnet system 60 according to FIG. 6 is utilized.

As far as the determination of segments B, d and C is concerned, the plasma width B is not determined directly. B and d can therefore only be defined via the magnetic field, since it determines the plasma confinement. The plasma burns essentially at those sites at which the field lines, and consequently the magnetic field vector, extend parallel to the target surface. At these sites the component, perpendicular with respect to the target surface, of the magnetic field vector is zero. These sites can be determined experimentally by measuring the field strength on the target surface. The distance C between two regions 16, 17 of a plasma tube is therefore defined by the distance of the positions on the target surface in the direction of the relative movement, at which the perpendicular component of the field vector becomes zero. The diameter d of the plasma tube 9 is correspondingly defined as the distance of the positions on the target surface in the direction of the relative movement, at which the magnetic field vector forms an angle of 20° with the target surface. This corresponds to the sites at which the field lines intersect the target surface at an angle of 20°. The positions are located in the center of the longitudinal direction of target 2, thus approximately where the distance symbol for C is located in FIG. 1. The width B of the plasma tube at the narrow sides is defined as the maximum distance of the positions on the target surface in the direction of the relative movement, at which the magnetic field vector forms with the target surface an angle of 20°. Maximum distance in this connection means approximately the double arrow located in the center of FIG. 3. If it is shifted upwardly or downwardly, the distance becomes smaller.

Consequently, the values B, d and C can be determined precisely through measurements and/or calculations.

1. Sputter arrangement with a magnetron and a target, in which magnetron and target can be moved relative to one another and the magnetron comprises a magnet system with at least one inner magnet and at least one outer magnet surrounding it, and in which the magnet system forms at least one closed plasma tube between an inner and an outer magnet, which includes two regions at a distance c from one another, which extend substantially perpendicularly to the direction of movement of the magnetron relative to a substrate and which have a diameter d, characterized in that with a relative movement between target (2) and magnet system (1) by a path W≈C the magnet system (1) is laid out such that the widths B of the ends of the plasma tube (9) fulfill the condition B≦d.

2. Sputter arrangement with a magnetron and a target, in which magnetron and target can be moved relative to one another and the magnetron comprises a magnet system with at least one inner magnet and at least one outer-magnet surrounding it, and in which the magnet system forms at least one closed plasma tube between an inner and an outer magnet, which includes two regions at a distance C from one another, which extend substantially perpendicularly to the direction of movement of the magnetron relative to a substrate and which have a diameter d, characterized in that with a relative movement between target (2) and magnet system (1) by a path W>C the magnet system (1) is laid out such that the widths B of the ends of plasma tube (9) fulfill the condition B≦2d.

3. Sputter arrangement as claimed in claims 1 or 2, characterized in that the distance C between the two regions (16, 17) of the plasma tube (9) is defined by the distance of two positions on the surface of the target (2) in the direction of the relative movement, at which the component of the magnetic field vector perpendicular to the surface of the target (2) is zero.

4. Sputter arrangement as claimed in claims 1 or 2, characterized in that the diameter d of the plasma tube (9) is defined by the distance of two positions on the surface and in the center of the longitudinal direction of the target (2) in the direction of the relative movement, at which the field vector forms with the surface of the target (2) an angle of approximately 20°.

5. Sputter arrangement as claimed in claims 1 or 2, characterized in that the width B of the ends of the plasma tube (9) corresponds to the maximum distance of the positions on the surface of the target (2) in the direction of the relative movement, at which the magnetic field vector forms an angle of approximately 20° with the surface of the target (2).

6. Sputter arrangement as claimed in claims 1 or 2, characterized in that the relative movement is a back and forth movement.

7. Sputter arrangement as claimed in claims 1 or 2, characterized in that the outer magnet (25) comprises two long parallel bar magnets (32, 33), whose ends are terminated by two small bar magnets (34, 35; 36, 37) forming a roof.

8. Sputter arrangement as claimed in claim 7, characterized in that the inner bar magnet has a smaller diameter (n, o) at its ends than at its center (m).

9. Sputter arrangement as claimed in claims 1 or 2, characterized in that three inner (61 to 63) and several outer magnets (64 to 75) are provided, and a region of a first outer magnet (67) forms simultaneously a region of a second outer magnet and a region of the second outer magnet (66) forms simultaneously a region of a third outer magnet.

10. Sputter arrangement as claimed in claim 9, characterized in that the first and the third outer magnet comprise in each instance two bar magnets (64, 66; 65, 67) disposed parallel to one another, of which the one bar magnet (66, 67) is shorter than the other (64, 65), and that the ends of the two bar magnets are connected with one another by an L-form magnet configuration (70, 91; 73, 79 or 68, 74; 71, 76) each.
